(19) United States
(12) Patent Application Publication
(10) Pub. No.: US 2026/0190712 A1
(43) Pub. Date: Jul. 2, 2026

(54) Display Device

(71) Applicant: LG Display Co., Ltd., Seoul (KR)

(72) Inventor: In Tae Ko, Paju-si (KR)

(21) Appl. No.: 19/427,824

(22) Filed: Dec. 19, 2025

(30) Foreign Application Priority Data
Dec. 30, 2024 (KR) 10-2024-0200895

(51) Int. Cl. H10K 59/131; H10K 59/80

(52) U.S. Cl. CPC H10K 59/131; H10K 59/8792

(57) ABSTRACT

A display device includes a substrate having a non-rectangular active area and a non-active area surrounding the active area, a plurality of emission areas and a plurality of first transmissive areas provided in the active area, a plurality of data lines and a plurality of first voltage lines disposed in a first direction and overlapping at least one of the plurality of emission areas, a capacitance compensation part disposed in the non-active area and connected to at least one data line extended to the non-active area among the plurality of data lines and an encapsulation layer over the plurality of emission areas and the plurality of first transmissive areas in the active area, and the capacitance compensation part in the non-active area.

### CROSS-REFERENCE TO RELATED APPLICATIONS

This application claims the benefit of Korean Patent Application No. 10-2024-0200895, filed on Dec. 30, 2024, which is hereby incorporated by reference as if fully set forth herein.

### BACKGROUND OF THE DISCLOSURE

### Field of the Disclosure

The present disclosure relates to a display device, and more specifically, to a non-rectangular display device that implements transparent display.

### Discussion of the Related Art

Display devices that display images on TVs, monitors, smartphones, tablets, and laptops are being used in various methods and forms.

These display devices do not require a separate light source, and compactness of devices and clear color display are required. Accordingly, self-luminous display devices such as organic light-emitting display devices and quantum dot light-emitting display devices are being considered as competitive applications.

A self-luminous display device has a plurality of pixels on a substrate and includes a light-emitting diode having two electrodes facing each other and an emission layer therebetween in each pixel.

Recently, application of such self-luminous display devices to transparent display devices capable of emission and transparent display simultaneously is being considered.

### SUMMARY OF THE DISCLOSURE

Accordingly, the present disclosure is directed to a display device that substantially obviates one or more problems due to limitations and disadvantages of the related art.

An aspect of embodiments of the present disclosure is to provide a display device for providing transparency in a non-active area as well as an active area.

An aspect of the embodiments of the present disclosure is to provide a display device for preventing perception of a difference between an active area and an adjacent non-active area.

An aspect of the embodiments of the present disclosure is to provide a display device for preventing charge amount deviation due to a wiring line length difference between areas in a non-rectangular active area.

An aspect of the embodiments of the present disclosure is to provide a display device for preventing luminance unevenness or preventing luminance unevenness from being visible.

An aspect of the embodiments of the present disclosure is to achieve ESG (Environmental/Social/Governance) from the viewpoint of preventing luminance unevenness and enhancing visibility of a display device including a transmissive area.

Additional advantages, aspects, and features of the present disclosure will be set forth in part in the description which follows and in part will become apparent to those having ordinary skill in the art upon examination of the following or may be learned from practice of the present disclosure. The aspects and other advantages of the present disclosure may be realized and attained by the structure particularly pointed out in the written description and claims hereof as well as the appended drawings.

To achieve these aspects and other advantages and in accordance with the purpose of the present disclosure, as embodied and broadly described herein, a display device includes a substrate having a non-rectangular active area and a non-active area surrounding the active area, a plurality of emission areas and a plurality of first transmissive areas provided in the active area, a plurality of data lines and a plurality of first voltage lines disposed in a first direction and overlapping at least one of the plurality of emission areas, a capacitance compensation part disposed in the non-active area and connected to at least one data line extended to the non-active area among the plurality of data lines and an encapsulation layer over the plurality of emission areas and the plurality of first transmissive areas in the active area, and the capacitance compensation part in the non-active area.

In another aspect of the present disclosure, a display device includes a substrate having an active area including a plurality of subpixels and a non-active area surrounding the active area, a plurality of data lines and a plurality of first voltage lines provided in a first direction in the active area, a data capacitance compensation part disposed in the non-active area and connected to a data line adjacent to the non-active area among the plurality of data lines, and a dummy pixel part provided between the active area and the data capacitance compensation part, wherein the active area includes first transmissive areas and the non-active area includes second transmissive areas.

It is to be understood that both the foregoing general description and the following detailed description of the present disclosure are exemplary and explanatory and are intended to provide further explanation of the present disclosure as claimed.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a plan view showing a display device according to an embodiment of the present disclosure;

FIG. 2 is an enlarged view of area A of FIG. 1;

FIG. 3 is a pixel circuit diagram according to an example of a subpixel in an active area of FIG. 1 according to an example.

FIG. 4 is a pixel circuit diagram according to another example of a subpixel in the active area of FIG. 1;

FIG. 5 is a plan view showing a compensation area, a dummy pixel part, and an active area of FIG. 2;

FIG. 6 is a plan view showing area APR of FIG. 4;

FIG. 7 is a cross-sectional view taken along line I-I′ in FIG. 6;

FIG. 8 is a plan view showing a first emission area and an adjacent first transmissive area of the active area overlapping a data line and a reference line of FIG. 1, a capacitance compensation part and an adjacent third transmission area of a non-active area;

FIG. 9 is a cross-sectional view taken along line II-II′ in FIG. 5;

FIG. 10 is a cross-sectional view taken along line III-III′ in FIG. 5; and

FIG. 11 is a cross-sectional view taken along line IV-IV′ in FIG. 5.

### DETAILED DESCRIPTION OF THE DISCLOSURE

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

In the following description, when a detailed description of well-known functions or configurations related to this document is determined to unnecessarily cloud a gist of the inventive concept, the detailed description thereof will be omitted or may be briefly discussed.

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments may be provided so that this disclosure may be sufficiently thorough and complete to assist those skilled in the art to fully understand the scope of the present disclosure.

A shape, a size, a ratio, an angle, and a number disclosed in the drawings for describing embodiments of the present disclosure may be merely an example. Thus, the present disclosure is not limited to the illustrated details. Like reference numerals refer to like elements throughout. In the following description, when the detailed description of the relevant known function or configuration is determined to unnecessarily obscure an important point of the present disclosure, the detailed description of such known function or configuration may be omitted. When “comprise,” “have,” and “include” described in the present specification are used, another part may be added unless “only” is used. An element described in a singular form is intended to include a plurality of elements, and vice versa, unless the contrary context clearly indicates otherwise.

Any implementation described herein as an “example” is not necessarily to be construed as preferred or advantageous over other implementations.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

In the description of the various embodiments of the present disclosure, where positional relationships are described, for example, when a position relation between two parts is described as, for example, “on,” “over,” “under,” and “next,” or the like, one or more other parts may be located between the two parts unless a more limiting term, such as “just” or “direct(ly)” is used. For example, where an element or layer is disposed “on” another element or layer, a third layer or element may be interposed therebetween.

In describing a temporal relationship, when the temporal order is described as, for example, “after,” “subsequent,” “next,” and “before,” a case that is not continuous may be included unless a more limiting term, such as “just,” “immediate(ly),” or “direct(ly)” is used.

In describing elements of the present disclosure, the terms “first,” “second,” “A,” “B,” “(a),” and “(b),” etc. may be used. These terms may be merely for differentiating one element from another element, and the essence, sequence, order, or number of a corresponding element should not be limited by the terms. For example, a first element could be termed a second element, and, similarly, a second element could be termed a first element, without departing from the scope of the present disclosure.

Also, when an element or layer is “connected,” “coupled,” or “adhered” to another element or layer denotes that the element or layer can not only be directly connected or adhered to the other element or layer, but also be indirectly connected or adhered to the other element or layer with one or more intervening elements or layers “disposed,” or “interposed” between the elements or layers, unless otherwise specified. It should be understood to mean that elements may be so disposed to directly contact each other, or may be so disposed without directly contacting each other.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these embodiments may be provided so that this disclosure may be sufficiently thorough and complete to assist those skilled in the art to fully understand the scope of the present disclosure.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in co-dependent relationship.

Hereinafter, preferred embodiments of the present disclosure will be described with reference to the attached drawings.

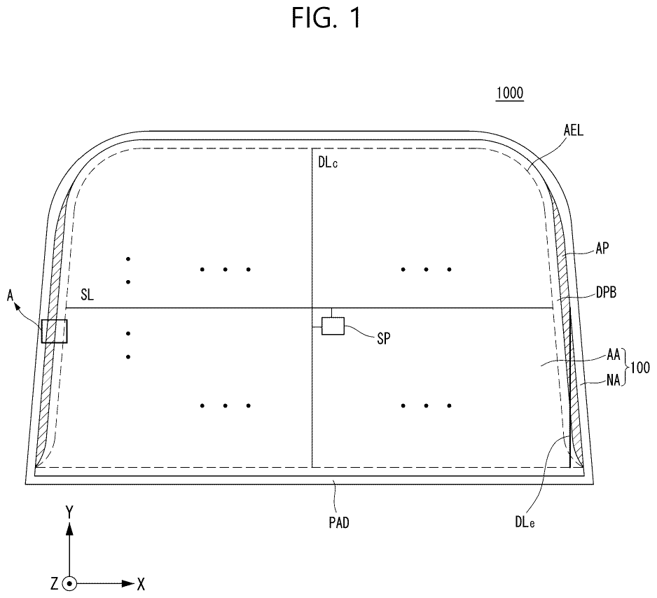

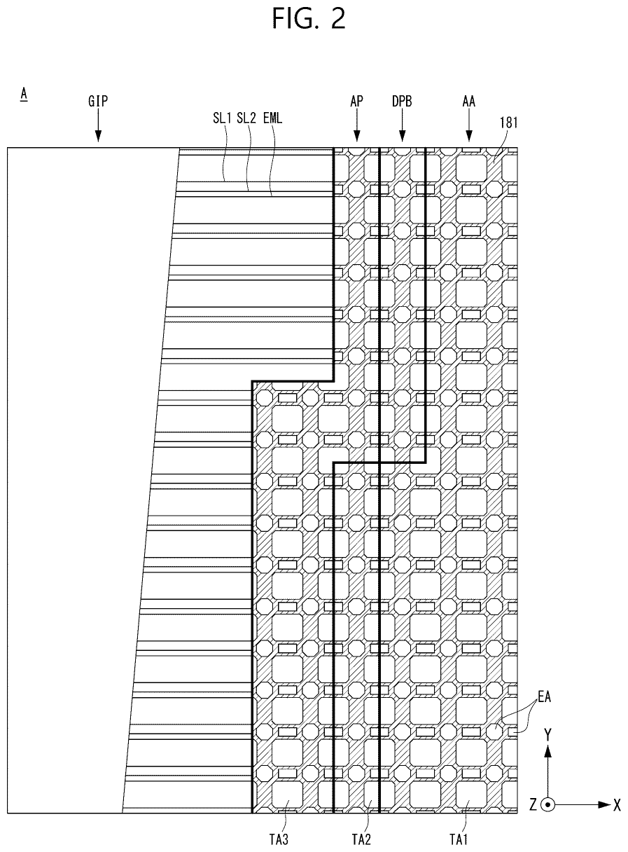

FIG. 1 is a plan view showing a display device according to an embodiment of the present disclosure. FIG. 2 is an enlarged view of area A of FIG. 1.

Referring to FIG. 1, a display device 1000 according to an embodiment of the present disclosure is a non-rectangular display device having a shape other than a rectangle. A non-rectangular display device means a display device having a shape other than a rectangular shape.

Examples of shapes of non-rectangular display devices include various shapes such as a circle, a partially curved shape having a curve selectively at a corner, a polygon other than a square, and an oval.

The display device 1000 illustrated in FIG. 1 includes a substrate 100 having an active area AA (inside the dotted line area) in the center and a non-active area NA surrounding the active area AA.

The active area AA of the substrate 100 illustrated in FIG. 1 has a non-rectangular shape, for example. In FIG. 1, the end line AEL of the active area AA is indicated by a dotted line. The inner side of the end line AEL of the active area AA may be the active area AA and the outer side may be a non-active area NA.

The lower side of the end line AEL of the active area AA in the X-axis direction is long and the upper side in the X-axis direction is relatively short. The end line AEL of the active area AA has symmetrical oblique sides between the upper and lower sides of the end line AEL. In addition, the end line AEL of the active area AA has curved portions between the oblique sides and the upper side.

The active area AA includes data lines DL in the Y-axis direction (first direction).

Since the active area AA has a length difference between the upper and lower sides and also has curved portions at the corners of the upper side, data lines DLe adjacent to the left and right sides of the end line of the active area AA among the data lines DL disposed in the Y-axis direction (first direction) are shorter than the data line DLc disposed in the center.

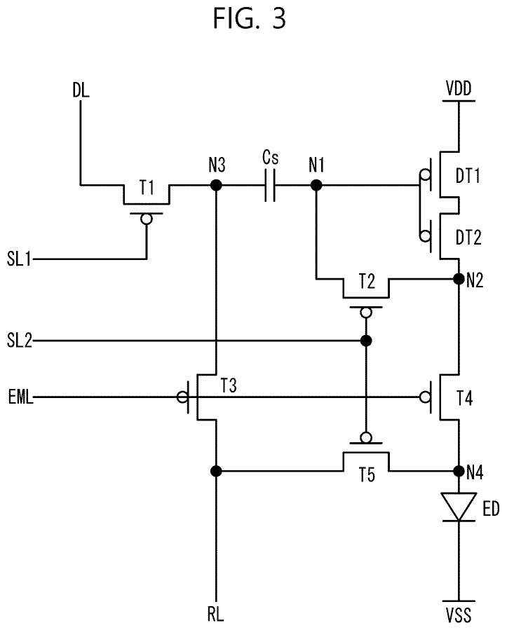

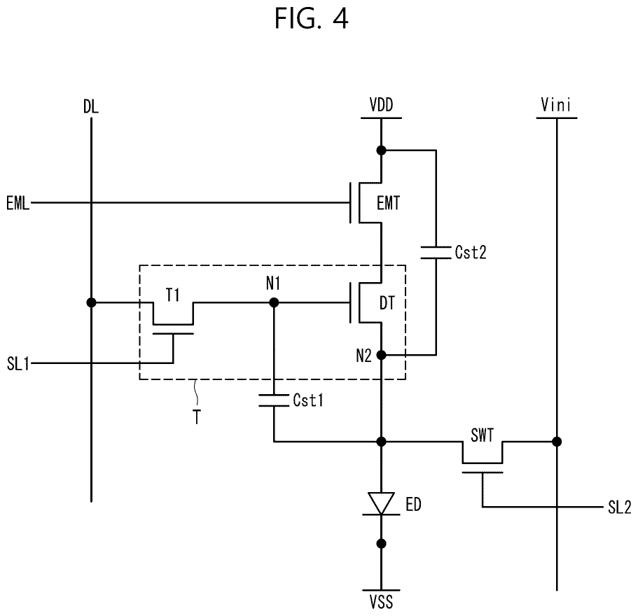

Meanwhile, at the active area AA, a plurality of scan lines SL (refer to SL1 and SL2 in FIG. 3 and FIG. 4) is disposed in the X-axis direction (second direction) to intersect the data lines DL (DLc and DLe).

The data lines DL (DLc and DLe) intersect the scan lines SL and secure capacitance, and the relatively short data line DLe and the relatively long data line DLc intersect different numbers of scan lines. That is, the relatively short data line DLe intersects a small number of scan lines, and thus the capacitance of the data line is small. A data line with a small capacitance has insufficient charge, causing a data voltage failure. In this case, luminance failure may occur in an area having insufficient charge of the data line.

In order to solve such insufficient charge of a data line, the display device according to an embodiment of the present disclosure includes a capacitance compensation part AP connected to a relatively short data line DLe in the non-active area NA to compensate for the insufficient charge of the data line DLe.

In the active area AA having a non-rectangular shape, relatively short data lines DLe may be connected to the capacitance compensation part AP of the non-active area NA. The capacitance compensation part AP may be in the form of a capacitor. A specific example will be described later.

Although the display device 1000 of FIG. 1 is illustrated as having a form in which the left and right edges of the active area AA have short areas in the first direction (Y-axis direction), the embodiment of the present disclosure is not limited thereto.

That is, the display device according to embodiments of the present disclosure is characterized by having the data capacitance compensation part connected to relatively short data lines DLe in a non-active area NA. The area where the short data lines DLe are disposed is related to the shape of the active area AA. For example, when an area having a short length in the first direction (Y-axis direction) is locally included in the lower part of the substrate 100, the data capacitance compensation part may be provided in the non-active area of the lower part of the substrate 100. In addition, in various non-rectangular display devices, when a plurality of lines is disposed in one direction in an active area, the capacitance compensation part AP may be applied to compensate for the amount of charge of each line when the plurality of lines has different lengths in the active area.

At least one side of the non-active area NA may be provided with a pad PAD. The pad PAD may include or be connected to a driver.

For example, the driver may be connected to the pad PAD of the substrate 100 in a COG (Chip On Glass) manner, or may be connected to a printed circuit board through a chip-on-film (COF) or a connector on the substrate 100. Alternatively, the driver may include components integrated into the substrate 100 and an external component of the COG or COF.

The active area AA is an area where an image is displayed. In the active area AA of the display panel DP, a plurality of subpixels SP connected to scan lines SL and data lines DL is disposed, and an image can be displayed using the plurality of subpixels SP. An area other than the active area AA may be a non-active area NA.

The active area AA can be referred as a display area and the non-active area NA can be referred as a non-display area.

As shown in FIG. 1, the capacitance compensation part AP may not be disposed in a curved portion at an outer edge (corner) of the non-active area NA. If the capacitance compensation part AP is applied to a curved portion at an outer edge, excessive capacitance compensation occurs, resulting in luminance deviation at the outer edge.

As shown in FIG. 2, the non-active area NA may include a gate-in-panel (GIP) that supplies scan signals to scan lines. The GIP is connected to the plurality of scan lines SL and/or emission control lines EML of the active area AA, and may sequentially supply gate voltage signals to the scan lines SL and sequentially supply emission control signals to the emission control lines EML.

Various additional elements for driving the subpixels SP within the active area AA may be further disposed in the non-active area NA.

Meanwhile, the non-active area NA closest to the active area AA may include a dummy pixel part DPB. The dummy pixel part DPB may include a configuration similar to that of the subpixels SP provided in the active area AA. The dummy pixel part DPB is positioned immediately outside the active area AA, and the capacitance compensation part AP may be disposed outside the dummy pixel part DPB. The dummy pixel part DPB may be disposed between the active area AA and the capacitance compensation part AP.

The dummy pixel part DPB may include a first electrode configuration including transistors and light-emitting elements having the same or similar sizes and shapes as those disposed at the edge of the adjacent active area AA.

The reason for providing the dummy pixel part DPB outside the active area AA is as follows. Each subpixel SP within the active area AA includes thin film transistors and a light-emitting element. However, if there is no pattern at all immediately outside components of subpixels located at the outermost part of the active area AA, a pattern density difference between the outermost part of the active area AA and the non-active area immediately outside the active area AA may cause the critical dimension (CD) of patterns to fluctuate significantly at the outermost part of the active area AA during an etching process for forming patterns, and the patterns of the subpixels at the outer most part may have a different shape from the patterns of the subpixels in the center of the active area AA. The display device of the embodiments of the present disclosure may include the dummy pixel part including dummy pixels identical or similar to the subpixels SP of the active area AA outside the outermost part of the active area AA, such that uniform subpixel patterns are disposed at the outermost part and the center of the active area AA.

The dummy pixel part DPB may be in contact with the end line AEL of the active area AA.

As shown in FIG. 2, the display device of the present disclosure may include transmissive areas TA1, TA2, and TA3 in the active area AA, the dummy pixel part DPB, and the capacitance compensation part AP, respectively.

The transmissive areas TA, T2, and T3 may be defined as openings of a light-shielding layer 181 positioned on an encapsulation layer including transistors and light-emitting elements formed on the substrate 100. Accordingly, each of the transmissive areas TA1, TA2, and TA3 may be surrounded by the light-shielding layer 181. The light-shielding layer 181 may have openings of the same size in the transmissive areas TA1, TA2, and TA3 and may have similar transmittance and similar visual sensation.

The light-shielding layer 181 may further include openings corresponding to emission areas EA in addition to the transmissive areas TA1, TA2, and TA3 in the active area AA. The emission areas EA may have different sizes, shapes, or arrangement densities depending on the degree to which emitted colors contributes to white expression. The dummy pixel part DPB and the capacitance compensation part AP having the same shape as the emission areas EA of the active area AA may be provided.

The density of patterns of each layer for components of the transistors and light-emitting elements on the substrate 100 is similar or identical to that of the active area AA and the dummy pixel part DPB immediately adjacent to the outer edge of the active area AA. This prevents uneven pattern formation caused by a difference in pattern density in an etching process for forming patterns, and enables accurate formation of patterns even at the outside and edge of the active area AA.

Referring to FIG. 2, in the display device of the embodiments of the present disclosure, the scan lines SL1 and SL2 and the emission control line EML extend from the active area AA to the dummy pixel part DPB and the capacitance compensation part AP and are connected to the GIP. The same gate voltage signal may be applied through the scan lines SL1 and SL in the same row in each of the areas AA, DPB, and AP, and the same emission control signal may be applied through the emission control line EML in the same row in each of the areas AA, DPB, and AP.

In the area where the capacitance compensation part AP is located, data lines DL passing through the capacitance compensation part AP passes through the active area AA in the first direction (Y-axis direction) and a capacitance-compensated data signal may be applied through the capacitance compensation part AP.

Hereinafter, the configuration and operation of a subpixel will be described with reference to the circuit diagram of the sub-pixel.

FIG. 3 is a pixel circuit diagram according to an example of a subpixel in the active area of FIG. 1.

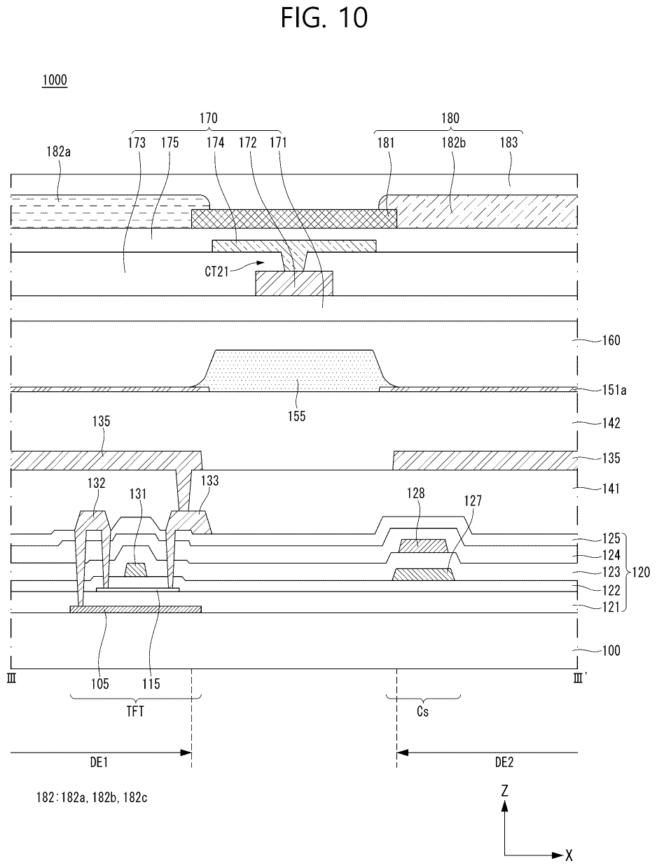

Referring to FIG. 3, in the display device according to an embodiment of the present disclosure, each subpixel SP includes a first transistor T1, a second transistor T2, a third transistor T3, a fourth transistor T4, a fifth transistor T5, driving transistors DT1 and DT2, a storage capacitor Cs, and a light-emitting element ED (refer to 150 in FIG. 10).

In FIG. 3, the first to fifth transistors T1, T2, T3, T4, and T5 and the driving transistors DT1 and DT2 are all illustrated as P-type transistors. The P-type transistor can be turned on when a low signal is applied to the gate electrode. However, the display device of the embodiments of the present disclosure is not limited thereto. At least one of the first to fifth transistors T1, T2, T3, T4, and T5 and the driving transistors DT1 and DT2 may be an N-type transistor.

The input terminals of the driving transistors DT1 and DT2 are defined as a first node N1, and the output terminal is defined as a second node N2. The gate electrodes of the driving transistors DT1 and DT2 are provided as the input terminals, first source-drain electrodes thereof are connected to a line through which a high-level driving voltage VDD is supplied, and second source-drain electrodes thereof are provided as the output terminals.

The storage capacitor Cs is disposed between the first node N1 and a third node N3. The light-emitting element ED is disposed between a fourth node N4 and a line through which a low-level driving voltage VSS is supplied. The fourth transistor T4 operated by an emission control line EML is disposed between the second node N2 and the fourth node N4.

The gate electrode of the first transistor T1 is connected to the first scan line SL1, and the first source-drain electrode and the second source-drain electrode thereof are connected to a data line DL and the third node N3. The first transistor T1 receives a first gate voltage signal through the first scan line SL1 and is switched to supply a data signal to the third node N3. The data signal is charged in the storage capacitor Cs located between the third node N3 and the first node N1.

The gate electrodes of the second transistor T2 and the fifth transistor T5 are connected to the second scan line SL2 and receive a second gate voltage signal. Supply of the first gate voltage signal through the first scan line SL1 and supply of the second gate voltage signal through the second scan line SL2 are optional. Therefore, the operation of the first transistor T1 according to the first gate voltage signal and the operations of the second and fifth transistors T2 and T5 according to the second gate voltage signal are optional.

The first source-drain electrode of the second transistor T2 is connected between the first node N1 located on the opposite side of the third node N3 with the storage capacitor Cs interposed therebetween and the second node N2 serving as the output terminals of the driving transistors DT1 and DT2. The second transistor T2 may receive the second gate voltage signal through the second scan line SL2 to transmit a switching signal charged in the third node N3 to the second node N2.

In the example illustrated in FIG. 3, the two driving transistors DT1 and DT2 are connected in series, but the embodiment of the present disclosure is not limited thereto, and a single driving transistor DT1 may be provided. When the driving transistors DT1 and DT2 are connected in series, a transistor having a short channel can be used as each of the driving transistors DT1 and DT2, which is advantageous for a high-resolution structure.

The driving transistors DT may receive the data signal charged in the first node N1 according to the operation of the first transistor T1 and transmit a driving current to the second node N2.

The gate electrode of the third transistor T3 is connected to the emission control line EML, and the first and second source/drain electrodes thereof are connected to the third node N3 and a reference line RL. The gate electrode of the fourth transistor T4 is connected to the emission control line EML, and the first and second source/drain electrodes thereof are connected to the second node N2 and the fourth node N4. The fifth transistor T5 is connected between the reference line RL and the fourth node N4. An initialization voltage Vini or a reference voltage may be supplied through the reference line RL.

The third and fourth transistors T3 and T4 operate together according to the light emission control signal, supply a reference signal to the third node N3, and selectively supply the reference signal to the fourth node N4 according to the second gate voltage signal.

The light-emitting element ED is disposed between the fourth node N4 and a line through which a low-level driving voltage VSS is supplied.

When the first gate voltage signal is supplied to the light-emitting element ED through the first scan line SL1, the first transistor T1 operates and the driving transistor DT transmits the driving current to the second node N2 according to the data signal supplied to the first node N1, and when the light emission control signal is supplied through the light emission control line EML, the driving current is transmitted from the second node N2 through the fourth node N4 to the light-emitting element ED through the fourth transistor T4. When the second gate voltage signal is supplied through the second scan line SL2, the second transistor T2 and the fifth transistor T5 operate to supply a reference voltage to the light-emitting element ED and initialize the light-emitting element ED.

When the initialization voltage is applied to the first electrode of the light-emitting element ED, the light-emitting element ED is initialized, or when the high-level driving voltage VDD is applied to the first electrode of the light-emitting element ED, the light-emitting element ED emits light as the current moves in the direction of the low-level driving voltage VSS.

The light-emitting element ED represents one of white, red, green, and blue and can emit light through an emission area of the subpixel SP.

Each of the transistors T1, T2, T3, T4, T5, DT1, and DT2 of the pixel circuit shown in FIG. 3 includes an active layer, a gate electrode, and first and second source-drain electrodes. The active layer may include at least one of a crystalline silicon layer, an amorphous silicon layer, or an oxide semiconductor layer.

Another example of a pixel circuit will be described below.

FIG. 4 is a pixel circuit diagram according to another example of a subpixel in the active area of FIG. 1.

Referring to FIG. 4, in a display device according to an embodiment of the present disclosure, each subpixel SP includes a first transistor T1, an emission control transistor EMT, a driving transistor DT, a switching transistor SWT, a first storage capacitor Cst1, a second storage capacitor Cst2, and a light-emitting element ED (refer to 150 in FIG. 10).

In FIG. 4, the transistors T1, EMT, DT, and SWT are illustrated as N-type transistors. The N-type transistor can be turned on when a high signal is applied to the gate electrode. However, the display device of the embodiments of the present disclosure is not limited thereto. At least one of the transistors T1, EMT, DT, and SWT may be a P-type transistor.

The input terminal of the driving transistor DT is defined as a first node N1, and the output terminal is defined as a second node N2. The gate electrode of the driving transistor DT is provided as the input terminal, the first source-drain electrode thereof is connected in series with the emission control transistor EMT connected to a line through which the high-level driving voltage VDD is supplied, and the second source-drain electrode thereof is connected to the light-emitting element ED as the output terminal N2.

The light-emitting element ED may be disposed between the second node N2 and a line through which the low-level driving voltage VSS is supplied.

The first storage capacitor Cst1 is disposed between the first node N1 and the second node N2. The second storage capacitor Cst2 is disposed between the emission control transistor EMT and the driving transistor DT that are connected in series. One end of the second storage capacitor Cst2 is connected to the line through which the high-level driving voltage VDD is supplied, and the other end is connected to the second node N2.

The first and second storage capacitors Cst1 and Cst2 are connected to the first electrode (anode) of the light-emitting element ED and the second node N2, and thus the voltage charged to each storage capacitor can be supplied.

The gate electrode of the first transistor T1 is connected to the first scan line SL1, and the first source-drain electrode and the second source-drain electrode thereof are connected to a data line DL and the first node N1. The first transistor T1 receives the first gate voltage signal through the first scan line SL1, and is switched to supply a data signal to the first node N1. The data signal is supplied to the gate electrode of the driving transistor DT to turn on the driving transistor DT.

The emission control transistor EMT transmits current according to the high-level driving voltage VDD to the driving transistor DT according to an emission control signal supplied through the emission control line EML, and the driving transistor DT is turned on by the data signal supplied from the first transistor T1 to supply a driving current to the light-emitting element ED through the second node N2.

The second node N2 of the light-emitting element ED may be connected to the second scan line SL2 and may be initialized by receiving an initialization voltage Vini via the switching transistor SWT. Meanwhile, a line through which the initialization voltage Vini is supplied may be a reference line RL. The initialization voltage Vini or a reference voltage may be supplied through the reference line RL.

Each of the transistors T1, DT, EMT, and SWT of the pixel circuit of FIG. 4 described above includes an active layer, a gate electrode, and first and second source-drain electrodes. The active layer in each of the transistors T1, DT, EMT, and SWT of the pixel circuit of FIG. 4 may include at least one of an oxide semiconductor layer, a crystalline silicon layer, or an amorphous silicon layer. For example, as shown in FIG. 4, at least transistors T including the first transistor T1 and the driving transistor DT of the pixel circuit may include an active layer made of an oxide semiconductor.

The first electrode (anode) of the light-emitting element ED is connected to the driving transistor DT or a switching transistor SWT, and the second electrode (cathode) of the light-emitting element ED is connected to a line (low-level line) through which a low-level driving voltage is supplied.

Accordingly, when the initialization voltage is applied to the first electrode of the light-emitting element ED, the light-emitting element ED is initialized, or the high-level driving voltage VDD is applied to the first electrode of the light-emitting element ED and the driving current transmitted through the turned-on emission control transistor EMT and the driving transistor DT moves in the direction of the low-level line, causing the light-emitting element ED to emit light. In an embodiment of the present disclosure, the low-level driving voltage VSS may be set to be lower than the high-level driving voltage VDD.

The light-emitting element ED may represent any one of white, red, green, and blue.

The pixel circuits of each subpixel of FIG. 3 and FIG. 4 are examples, and the numbers of transistors, storage capacitors, and compensation capacitors provided in the subpixel may vary in the display device of the embodiments of the present disclosure as needed.

In the pixel circuits of FIG. 3 and FIG. 4, the remaining transistors other than the driving transistors DT1, DT2, and DT may be switching transistors having a switching function.

The illustrated examples show a configuration including the first and second scan lines SL1 and SL2, the emission control line EML, the data line DL, and the reference line RL. Transistors other than those illustrated in FIG. 3 or FIG. 4 may be added or the transistors illustrated in FIG. 3 or FIG. 4 may be omitted.

The display device of the embodiments of the present disclosure includes the capacitance compensation part AP in a non-active area NA to compensate for a charge difference due to a data line length difference between areas in the active area AA. The capacitance compensation part AP provided in the non-active area NA is electrically connected to relatively short data lines DL in the active area AA.

The specific configurations of the active area, the dummy pixel part, and the capacitance compensation part will be described with reference to the drawings.

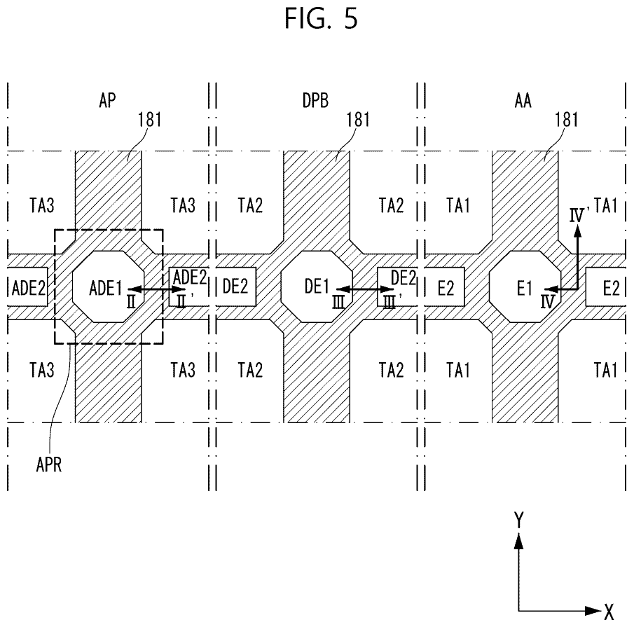

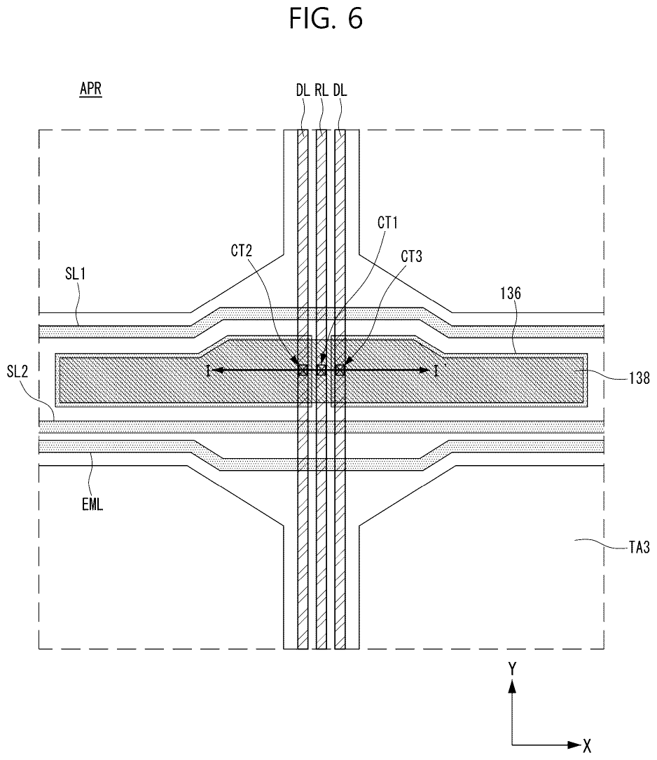

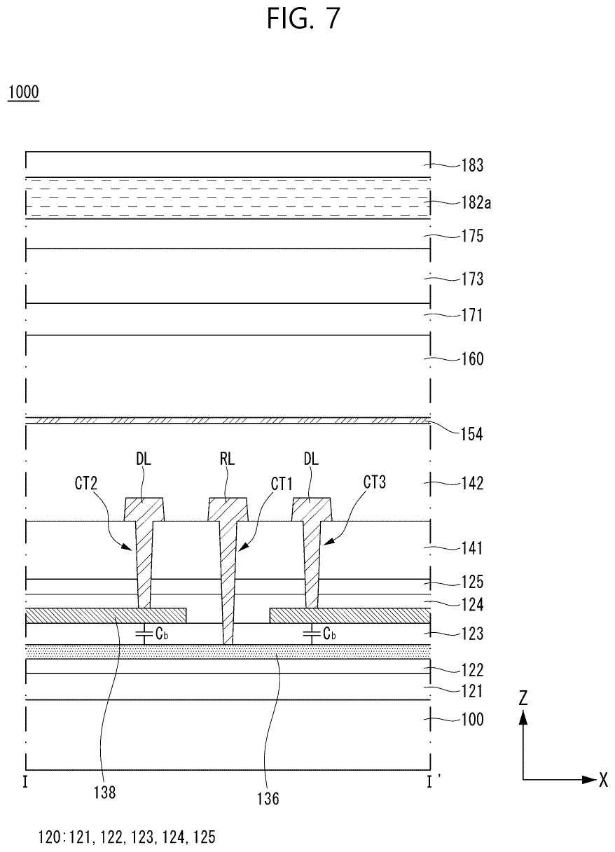

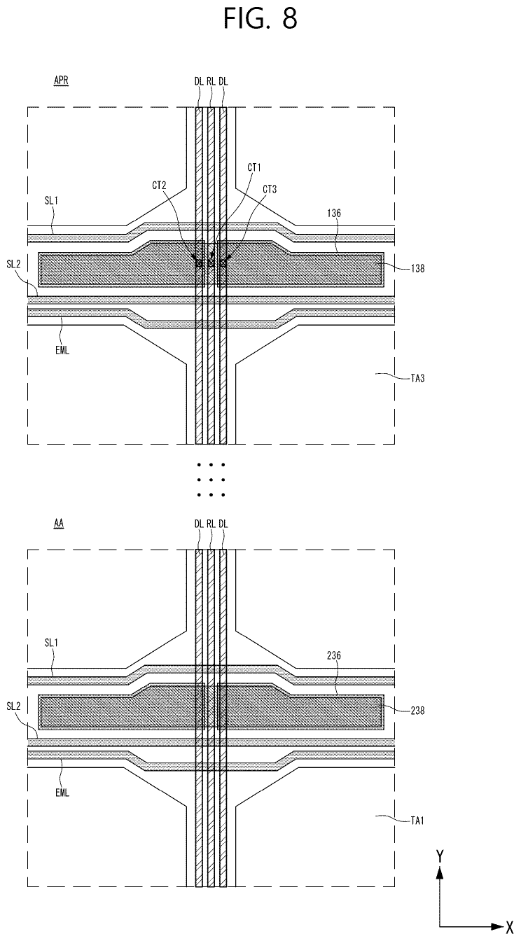

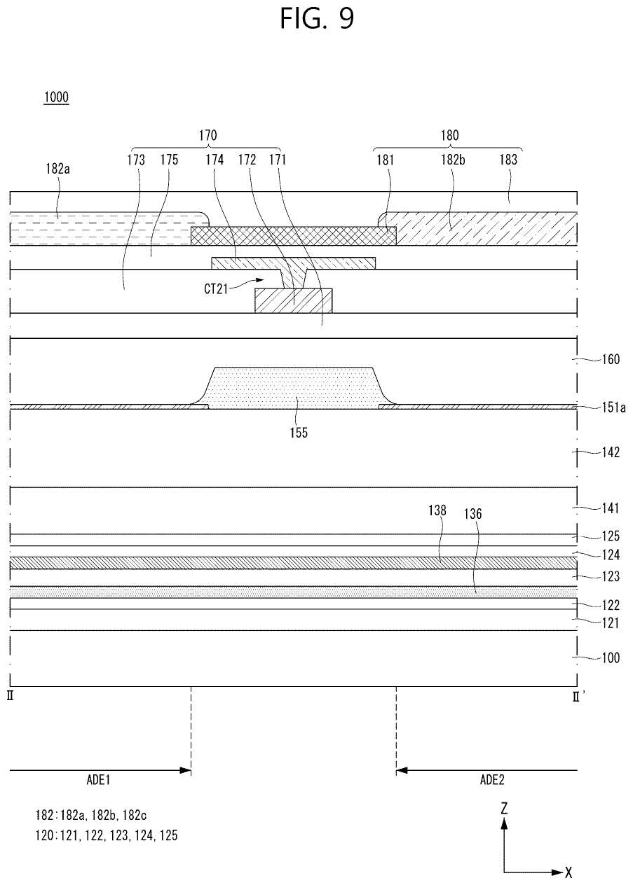

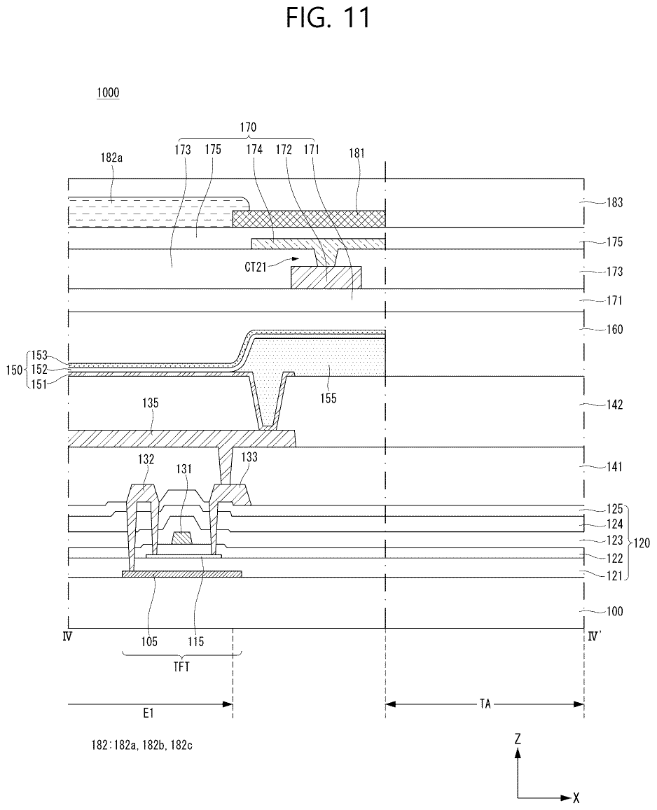

FIG. 5 is a plan view showing the compensation part, the dummy pixel part, and the active area of FIG. 2. FIG. 6 is a plan view showing area APR of FIG. 4. FIG. 7 is a cross-sectional view taken along line I-I′ in FIG. 6. FIG. 8 is a plan view showing a first emission area and a surrounding first transmissive area of the active area overlapping the data lines and the reference line of FIG. 1, and the capacitance compensation part and a surrounding third transmissive area of the non-active area. FIG. 9 is a cross-sectional view taken along line II-II′ in FIG. 5. FIG. 10 is a cross-sectional view taken along line III-III′ in FIG. 5. FIG. 11 is a cross-sectional view taken along line IV-IV′ in FIG. 5.

As shown in FIG. 5, in the display device according to an embodiment of the present disclosure, the active area AA, the dummy pixel part DPB and the capacitance compensation part AP located outside the active area AA include the light-shielding layer 181, and first to third transmissive areas TA1, TA2, and TA3 are defined by openings of the light-shielding layer 181. Openings corresponding to emission areas E1 and E2 are included in the light-shielding layer 181 surrounding the first transmissive area TA1 in the active area AA. The emission areas E1 and E2 emitting different colors may have different sizes and/or areas.

Here, the emission areas E1 and E2 each correspond to a subpixel SP and may include the pixel circuit of the subpixel SP of FIG. 3 or FIG. 4.

Referring to FIG. 10, the emission area E1 includes a transistor TFT and a light-emitting element 150 connected to the transistor TFT on a substrate 100.

The dummy pixel part DPB may have openings DE1 and DE2 of the light-shielding layer 181 in the same or similar shape as the emission areas E1 and E2 of the active area AA. Similarly, the capacitance compensation part AP may also include openings ADE1 and ADE2 of the light-shielding layer 181 in the same or similar shape as the emission areas E1 and E2 of the active area AA.

As shown in FIG. 5, the dummy pixel part DPB and the capacitance compensation part AP include the transmissive areas TA2 and TA3 and the dummy patterns DE1 and DE2 and the openings ADE1 and ADE2 of the light-shielding layer 181, which are identical or similar to the first transmissive areas TA1 and the emission areas E1 and E2 of the active area AA, and thus the outer edge of the active area AA and the non-active area NA outside the active area AA are viewed as a naturally connected area, and high picture quality can be provided.

As shown in FIG. 5 to FIG. 11, the display device according to an embodiment of the present disclosure includes the substrate 100 having a non-rectangular active area AA and a non-active area NA surrounding the active area AA, a plurality of emission areas EA1 and EA2, a plurality of first transmissive areas TA1 provided in the active area AA, a plurality of data lines DL and a plurality of reference lines RL provided in the first direction (Y-axis direction) and overlapping at least one of the plurality of emission areas EA1, EA2, . . . , and the capacitance compensation part AP connected to at least one data line DL extended to the non-active area among the plurality of data lines DL.

Here, the data lines DL are lines through which a data signal is supplied, and the reference lines RL are voltage lines through which a voltage signal of a reference voltage or an initialization voltage is supplied.

The encapsulation layer 160 is provided on the emission areas EA1, EA2, . . . , the first transmissive areas TA1, and the capacitance compensation part AP of the non-active area NA to protect components thereunder.

Referring to FIG. 5 to FIG. 7, the capacitance compensation part AP may include a first connection pattern 138 connected to at least one data line DL, a second connection pattern 136 connected to a reference line RL extended to the non-active area NA among the plurality of reference lines RL, and at least one insulating layer 123 between the first connection pattern 138 and the second connection pattern 136. The reference line RL is connected to the second connection pattern 136 through a first contact hole CT1, and data lines DL on both sides of the reference line RL are connected to the first connection patterns 138 spaced apart from each other through second and third contact holes CT2 and CT3.

The capacitance compensation part AP includes a compensation capacitor Cb connected to the data line DL in the circuit.

As shown in FIG. 8, the capacitance compensation part AP may be provided for shorter data lines (refer to DLe of FIG. 1) rather than the longest data line (refer to DLc of FIG. 1) in the first direction (Y-axis direction) overlapping the active area AA among the plurality of data lines DL in the active area AA. Therefore, the capacitance compensation part AP can transfer capacitance caused by a difference between a data voltage and a reference voltage in the capacitor Cb between the overlapped second connection pattern 136 and first connection pattern 138 to the data line DL connected to the first connection pattern 138 in response to a reference voltage signal supplied to the reference line RL, thereby compensating for insufficient charge amounts of the shorter data lines DL in the active area AA.

As shown in FIG. 8, the data lines DL extend from the active area AA to the capacitance compensation part AP in the non-active area NA, and the reference line RL extends from the active area AA to the capacitance compensation part AP in the non-active area NA in the first direction (Y-axis direction).

The second connection pattern 136 and the first connection pattern 138 of the capacitance compensation part AP provided in the non-active area NA of the substrate 100 may be the same layer as one electrode constituting a thin film transistor TFT in the active area AA. Each subpixel SP of the active area AA may include various transistors, as shown in FIG. 3 and FIG. 4, and may have different layer structures. For example, the first to fifth transistors T1, T2, T3, T4, and T5 of FIG. 3 include an active layer made of crystalline silicon, the driving transistors DT1 and DT2 include an active layer made of an oxide semiconductor, and the transistors including the crystalline silicon active layer and the transistors including the oxide semiconductor active layer may include active layers, gate electrodes, and first and second source-drain electrodes on different layers.

Here, the second connection pattern 136 of the capacitance compensation part AP may be provided on the same layer as the gate electrode of a transistor including a crystalline silicon layer, for example, and the first connection pattern 138 may be provided on the same layer as a light-shielding pattern or the gate electrode of a transistor including an oxide semiconductor layer. However, this is an example, and when transistors including various laminated structures are provided on a substrate, each connection pattern of the capacitance compensation part AP may be formed together with one of the electrodes of the transistors on the same layer, and thus the first and second connection patterns 138 and 136 can be formed together in the process of forming the transistors without adding a separate layer. Accordingly, it is possible to reduce the number of masks, minimize or reduce generation of greenhouse gases during the process, and achieve process optimization.

The data lines DL and the reference line RL may be disposed on the same layer in the same first direction (Y-axis direction). For example, the data lines DL and the reference line RL may be disposed on the same layer as the first and second source-drain electrodes (refer to 132 and 133 in FIG. 11) of at least one transistor TFT provided in the active area AA on the substrate 100.

However, this is an example, and the data lines DL and the reference line RL may be disposed on different layers in the display device of the embodiments of the present disclosure.

The reference line RL may be connected to the second connection pattern 136 through the first contact hole CT at a relatively deeper position than the data lines DL, and the first connection pattern 138 may be connected to different data lines DL located on both sides of the reference line RL through the second and third contact holes CT2 and CT3 at a distance from the reference line RL and the portion through which the reference line RL penetrates.

At least one insulating layer 121 and 122 may be disposed between the substrate 100 and the second connection pattern 136, at least one insulating layer 123 may be disposed between the second connection pattern 136 and the first connection pattern 138, and at least one insulating layer 124, 125, and 141 may be disposed between the first connection pattern 138 and the data lines DL and the reference line RL except for the first to third contact holes CT1, CT2, and CT3.

For example, the first to fifth insulating layers 121, 122, 123, 124, and 125 sequentially disposed on the substrate 100 may be inorganic insulating layers. The inorganic insulating layers may include, for example, a buffer layer, a gate insulating layer included in a transistor TFT, an interlayer insulating layer for insulation between layers of electrodes, etc. The inorganic insulating layers may be formed of, for example, silicon oxide, silicon nitride, silicon oxynitride, etc.

A first planarization layer 141 may be disposed under the data lines DL and the reference lines RL. The first planarization layer 141 is disposed below the data lines DL and reference lines RL to eliminate surface steps between the data lines DL and reference lines RL and uniformize the capacitance characteristics in the capacitance compensation part AP.

A second planarization layer 142 may be provided on the data lines DL and the reference lines RL to protect the surfaces thereof and to planarize the surface of light-emitting elements 150 formed thereafter.

A first electrode dummy pattern 154 made of the same layer and/or the same material as the first electrode 151 of the light-emitting element 150 of the active area AA may be further disposed on the capacitance compensation part AP. The first electrode dummy pattern 154 may cover the first and second connection patterns 138 and 136 that constitute the capacitance compensation part AP, the data lines DL, and the reference lines RL including reflective electrodes, and prevent or reduce external visibility. Therefore, as shown in FIG. 5, even if the first and second connection patterns 138 and 136 that constitute the capacitance compensation part AP are located in the openings ADE1 and ADE2 of the light-shielding layer 181, they may not be visible.

The first electrode dummy pattern 154 may be covered by the encapsulation layer 160.

Insulating layers 171, 173, and 175 of a touch sensor 170 may be provided on the encapsulation layer 160. The insulating layers 171, 173, and 175 of the touch sensor 170 may include a touch buffer layer 171, a touch insulating layer 173, and a touch protective layer 175.

The light-shielding layer 181 and a color filter layer may be further provided on the touch sensor 170 to prevent or reduce external light from being visible. In FIG. 7, an example in which an upper protective layer 183 is provided on the touch sensor 170 in the capacitance compensation part AP is shown, but in some cases, the light-shielding layer 181 or the color filter layer may be further provided.

The substrate 100 supports and protects components disposed thereon. The substrate 100 may be transparent and may have flexibility. The substrate 100 may be made of, for example, glass or a plastic material.

In the display device 1000 of an embodiment of the present disclosure, the substrate 100 may be formed of multiple layers, and may be formed, for example, in a form in which an interlayer inorganic layer is disposed between different flexible substrates.

In the display device 1000 of an embodiment of the present disclosure, the substrate 100 includes emission areas EA1, EA2, and EA3 and the first transmissive areas TA1 spaced apart from each other in the active area AA, as shown in FIG. 5 and FIG. 11. The first transmissive areas TA1 do not overlap lines including the first and second scan lines SL1 and SL2, the emission control line EML, the data lines DL, and the reference lines RL, and components including a light-blocking metal material such as transistors, thereby increasing the transmittance of light passing through the substrate 100. Accordingly, an object or image located under the substrate 100 can be observed from the outside of the uppermost component of the substrate 100. The emission areas E1 and E2 include light-emitting element (ED) 150 and may overlap at least the transistor TFT among the components below the light-emitting element 150. In addition, at least one of the first and second scan lines SL1 and SL2 and the emission control line EML may be disposed to overlap the first emission area E1 and/or the second emission area E2.

The first emission area E1 is located at the intersection of a column in the Y-axis direction and a row in the X-axis direction in the matrix shape of the light-shielding layer 181. In this case, as shown in FIG. 8, the first emission area E1 may overlap wiring lines including the data lines DL and the reference lines RL in the first direction (Y-axis direction). The second emission area E2 disposed below the light-shielding layer 181 may not intersect the data lines DL and the reference lines RL. In some cases, the first emission area E1 may overlap the high voltage line VDDL of a different line from the data lines DL and the reference lines RL.

The light-emitting element 150 includes a first electrode 151 provided for each subpixel, an intermediate layer 152, and a second electrode 153 sequentially laminated on the first electrode 151. Light generated in the light-emitting element 150 is emitted from the second electrode 153 in the emission areas E1 and E2, and an image according to the operation of the light-emitting element ED can be observed outside the uppermost component of the substrate 100.

The active area AA and the dummy pixel part DPB disposed on the substrate 100 may include transistors TFT and storage capacitors Cs of the same shapes. However, in the dummy pixel part DPB, the first electrode dummy pattern 151a and the transistor TFT thereunder are not electrically connected, and thus no light emission occurs.

The transistor TFT provided on the substrate 100 may include an active layer 115, a gate electrode 131 overlapping the active layer 115 with a second insulating layer 122 interposed therebetween, a first source-drain electrode 132 and a second source-drain electrode 133 connected to both sides of the active layer 115. The active layer 115 may include a semiconductor material. The semiconductor material may be a silicon-based semiconductor material or an oxide-based semiconductor material.

A light-shielding pattern 105 may be further provided under the transistor TFT on the substrate 100, specifically, under the active layer 115. The light-shielding pattern 105 may block transmission of light from the lower side of the substrate 100 to the transistor TFT, thereby preventing or reducing abnormal phenomena such as photocurrent generation.

A first insulating layer 121 may be provided between the light-shielding pattern 105 and the active layer 115 on the substrate 100. The first insulating layer 121 may serve as a buffer layer. The first insulating layer 121 may have a function of preventing or reducing impurities included in the substrate 100 from being transferred to the active layer 115 and planarizing the surface on which the active layer 115 is formed. The first insulating layer 121 may cover the light-shielding pattern 105. The first insulating layer 121 may protect structures on the substrate 100 that are vulnerable to moisture penetration from moisture penetrating through the substrate 100 and planarize the surface of the substrate 100.

In some cases, one or more insulating layers may be provided between the light-shielding pattern 105 and the substrate 100 to prevent or reduce impurities from entering the array on the substrate 100 from the substrate 100 and to additionally protect the array on the upper side of the substrate 100.

The first source-drain electrode 132 may be connected to the light-shielding pattern 105 in addition to being connected to the active layer 115 to stabilize the potential of the light-shielding pattern 105.

The second insulating layer 122 between the active layer 115 and the gate electrode 131 may serve as a gate insulating layer.

Third and fourth insulating layers 123 and 124 may be provided between the gate electrode 131 and the first and second source-drain electrodes 132 and 133 for interlayer insulation. In the illustrated example, two insulating layers are provided, but the present disclosure is not limited thereto. For example, a single insulating layer may be provided between the gate electrode 131 and the first and second source-drain electrodes 132 and 133. Alternatively, three or more insulating layers may be provided between the gate electrode 131 and the first and second source-drain electrodes 132 and 133.

The electrodes of the transistor TFT and the electrodes of the storage capacitor Cs may be disposed on the same layer.

For example, when multiple inorganic layers are provided between the gate electrode 131 and the first and second source-drain electrodes 132 and 133, a first storage electrode 127 may be disposed on the same layer as the gate electrode 131, and a second storage electrode 128 may be disposed on the third insulating layer 123 covering the first storage electrode 127 and overlapping the first storage electrode 127.

The light-shielding pattern 105, the gate electrode 131, the first and second source-drain electrodes 132 and 133, and the first and second storage electrodes 127 and 128 may each include one of aluminum (Al), titanium (Ti), copper (Cu), chromium (Cr), molybdenum (Mo), and tungsten (W).

A plurality of transistors TFTs is provided in each subpixel SP, and some of the plurality of transistors may serve as switching transistors and others may serve as driving transistors. For different functions, a switching transistor and a driving transistor may have different lamination structures or may have different widths and/or lengths of active layer channels.

The second storage electrode 128 may have the same layer as one electrode of the transistor illustrated in FIG. 10 and FIG. 11 and other transistors.

The active area AA may include a plurality of scan lines SL1 and SL2 and an emission control line EML in a second direction (X-axis direction) intersecting the first direction (Y-axis direction). The scan lines SL1 and SL2 may sequentially pass through the dummy pixel part DPB and the capacitance compensation part AP and may be connected to the gate-in-panel (GIP) of the non-active area NA located outside the capacitance compensation part AP in the non-active area NA.

The first to fourth insulating layers 121, 122, 123, and 124 may each include an inorganic insulating layer, for example, a silicon oxide (SiOx) layer, a silicon nitride (SiNx) layer, or a laminate thereof.

A first planarization layer 141 and a second planarization layer 142 that protect the transistor TFT and the storage capacitor Cs may be provided on the fourth insulating layer 124. In some cases, the second planarization layer 142 may be omitted.

The first planarization layer 141 may be disposed on the transistor TFT or on the fourth insulating layer 124 to protect the transistor TFT and alleviate a step caused by the transistor TFT.

A connection electrode 135 or a shielding pattern may be further provided on the first planarization layer 141, corresponding to the circuit components of subpixels, such as the transistor TFT and the storage capacitor Cs. The connection electrode 135 may serve to electrically connect the transistor TFT and the first electrode 151 of the light-emitting element 150. The shielding pattern may serve to prevent or reducing the operation of the circuit components disposed thereunder from causing electrical interference with the operation of the light-emitting element 150 disposed thereabove.

The first and second planarization layers 141 and 142 cover the transistor TFT and are disposed on the fourth insulating layer 124 to provide a flat surface.

The first planarization layer 141 and the second planarization layer 142 may each include an organic material. The organic material may include one or more of acrylic resin, phenolic resin, polyimide resin, unsaturated polyester resin, polyamide resin, benzocyclobutene, polyphenylene resin, and polyphenylene sulfide resin.

In addition to the first to fourth insulating layers 121, 122, 123, and 124 described above, various functional organic layers or inorganic layers may be additionally provided between the substrate 100 and the first planarization layer 141.

In the transmissive area TA, at least one of the first to fourth insulating layers 121, 122, 123, and 124 and the first and second planarization layers 141 and 142 may be removed to reduce the path through which light propagates in the transmissive area TA, thereby increasing transparency. In the transmissive area TA, one of the first to fourth insulating layers 121, 122, 123, and 124 may be omitted instead of the first and second planarization layers 141 and 142, or the first and second planarization layers 141 and 142 and one of the first to fourth insulating layers 121, 122, 123, and 124 may be omitted together in the transmissive area TA.

The light-emitting element 150 is disposed on the second planarization layer 142. The light-emitting element 150 is connected to the connection electrode 135 through a contact hole that penetrates the second planarization layer 142, and the connection electrode 135 may be electrically connected to the transistor TFR through a contact hole that penetrates the first planarization layer 141. The light-emitting element 150 includes a first electrode 151, an intermediate layer 152, and a second electrode 153.

The first electrode 151 may serve as an anode. The first electrode 151 may be connected to the transistor TFT by passing through the second planarization layer 142 and the first planarization layer 141. In the illustrated example, the connection electrode 135 is further provided between the first electrode 151 and the transistor TFT, the transistor TFT and the connection electrode 135 are connected, and the connection electrode 135 and the first electrode 151 are connected. However, the second source/drain electrode 133 of the transistor TFT and the first electrode 151 of the light-emitting element 150 may be directly connected without the connection electrode 135.

The first electrode 151 may include a metal material having high reflectivity. For example, the first electrode 151 may be formed in a multilayer structure such as a laminated structure of aluminum (Al) and titanium (Ti) (Ti/Al/Ti), a laminated structure of aluminum (Al) and ITO (ITO/Al/ITO), an APC (Ag/Pd/Cu) alloy, a laminated structure of an APC alloy and ITO (ITO/APC/ITO), or a laminated structure of silver (Ag) and molybdenum/titanium alloy (Ag/MoTI), or may include a single-layer structure made of one material selected from silver (Ag), aluminum (Al), molybdenum (Mo), gold (Au), magnesium (Mg), calcium (Ca), or barium (Ba), or two or more alloy materials. The first electrode 151 may be referred to as a reflective electrode.

The intermediate layer 152 is provided on the first electrode 151. The intermediate layer 152 may include a hole injection layer, a hole transport layer, an organic emission layer, an electron transport layer, and an electron injection layer.

The edge of the first electrode 151 may overlap with a bank 155. An area of the first electrode 151 exposed from the bank 155 may be the emission area E1 or E2.

When different voltages are applied to the first electrode 151 and the second electrode 153, holes and electrons move to the organic emission layer through the hole injection layer and the hole transport layer, and the electron injection layer and the electron transport layer, holes and electrons recombine to form excitons in the organic emission layer, and the excitons drop from an excited state to a ground state, causing light emission.

The intermediate layer 152 may include at least one of a red emission layer emitting red light, a green emission layer emitting green light, or a blue emission layer emitting blue light. The red emission layer, the green emission layer, and the blue emission layer may be provided on the first electrode 151 for respective subpixels SP. The red emission layer may be disposed in a red subpixel, the green emission layer may be disposed in a green subpixel, and the blue emission layer may be disposed in a blue subpixel, but the present disclosure is not necessarily limited thereto and at least two organic emission layers among the red emission layer, the green emission layer, and the blue emission layer may be laminated and disposed in one subpixel SP.

Each layer of the intermediate layer 152 may be provided in common throughout the entire active area AA. In some cases, one layer of the intermediate layer 152 may be selectively provided in the emission area E1 or E2. The light-emitting element 150 may have a tandem configuration in which a plurality of stacks including an emission layer, a hole-transport common layer related to hole transport disposed under the emission layer, and an electron-transport common layer related to electron transport disposed under the emission layer is provided, and a charge generation layer is provided between the plurality of stacks. In the tandem configuration, each layer including the charge generation layer of the intermediate layer 152 may be a common layer disposed on the overall surface of the active area AA.

The intermediate layer 152 may be a white emission layer emitting white light. In this case, the organic emission layer of the intermediate layer 152 may be a common layer that is commonly disposed in the subpixels SP rather than in a patterned form.

The second electrode 153 may be a common layer that is commonly disposed in the subpixels SP and supplied with the same voltage. To this end, the second electrode 153 may be disposed to extend from the active area AA to a part of the non-active area NA.

The second electrode 153 may be a light-transmitting electrode. The second electrode 153 may include a transparent conductive material such as indium tin oxide (ITO) or indium zinc oxide (IZO) that can transmit light, or a semi-transmissive conductive material such as magnesium (Mg), silver (Ag), or an alloy of magnesium (Mg) and silver (Ag). When the second electrode 153 includes a semi-transmissive conductive material, the light emission efficiency can be increased by the microcavity effect. When the second electrode 152 includes a semi-transmissive conductive material, the second electrode 152 may be sufficiently thin to transmit light. For example, the thickness of the second electrode 152 may be 200 Å or less.

The first electrode 151 may prevent or reduce light generated in the intermediate layer 152 from being transmitted to a light-shielding component below the first electrode 151 by including a reflective electrode. The light generated in the intermediate layer 152 resonates between the second electrode 153 and the first electrode 151, and can finally be emitted upward through the second electrode 153. Since the first electrode 151 includes a reflective component, even if the first electrode 151 overlaps with wiring lines and the transistor TFT, light emitted from the light-emitting element 150 is visible in the emission area E1 or E2 without being affected by the arrangement of the wiring lines and the transistor TFT.

The intermediate layer 152 and the second electrode 153 among the components of the light-emitting element 150 may be independently disposed in the first transmissive area TA. In this case, the intermediate layer 152 and the second electrode 153 provided in the first transmissive area TA1 may be transparent or transmissive.

The first transmissive area TA1 does not have the first electrode 151 compared to the emission area E1 or E2. The intermediate layer 152 and the second electrode 153 may be provided independently in the first transmissive area TA1. At least one of the hole injection layer, the hole transport layer, the electron transport layer, and the electron injection layer of the intermediate layers 152 may extend laterally from the emission area E1 or E2 and may be provided in the first transmissive area TA1.

In some cases, the second electrode 153 may be omitted from the first transmissive area TA1, as shown in FIG. 11, to increase the transmittance of the first transmissive area TA1.

When the intermediate layer 152 and the second electrode 153 are provided in the first transmissive area TA1, the use of a fine metal mask (FMM) requiring a fine opening at the time of forming each layer of the intermediate layer 152 and the second electrode 153 can be omitted, and yield improvement and process simplification are expected.

The encapsulation layer 160 is provided on the light-emitting element 150 to protect and seal the light-emitting element.

The encapsulation layer 160 may be provided as a single layer or as a multilayer layer. When the encapsulation layer 160 is a multilayer layer, for example, an inorganic encapsulation layer and an organic encapsulation layer may be disposed in an alternating form. The uppermost layer and the lowermost layer of the encapsulation layer 160 may be inorganic encapsulation layers, which is advantageous in preventing or reducing external air such as moisture from penetrating.

The encapsulation layer 160 planarizes the surface unevenness of the light-emitting element 150. Accordingly, the touch sensor 170 provided on the encapsulation layer 160 and detecting an external touch is disposed on the flat encapsulation layer 160.

The touch sensor 170 may include a touch buffer layer 171 disposed on the encapsulation layer 160, a first wiring layer 172 disposed on the touch buffer layer 171, a touch insulating layer 173 covering the first wiring layer 172 and planarizing the surface, a second wiring layer 174 disposed on the touch insulating layer 173 and connected to a part of the first wiring layer 172, and a touch protection layer 175 disposed on the second wiring layer 174 and providing a flat surface of the color filter array. In some cases, either the touch buffer layer 171 or the touch protection layer 175 may be omitted. Here, the first wiring layer 172 and the second wiring layer 174 may be connected in a certain area through a contact hole CT21. A first touch electrode formed by the first and second wiring layers 172 and 174 connected through the contact hole CT21 and a second touch electrode disposed on the same layer as the second wiring layer 174 may perform touch detection when a sensing signal and a transmission signal are supplied thereto.

The touch buffer layer 171, the touch insulating layer 173, and the touch protection layer 175 may be inorganic layers made of silicon oxide (SiOx), silicon nitride (SiNx), or silicon oxynitride (SiOxNy), or organic layers made of acrylic resin, epoxy resin, ester-based resin, polyimide-based resin, or polyamide-based resin.

A color filter array 180 including the light-shielding layer 181 disposed in an area other than the emission area E1 or E2 and the first transmissive area TA1, and color filters 182 (182a, 182b, and 182c) disposed to correspond to the emission area E1 or E2 may be provided on the touch sensor 170. For example, the color filters 182 (182a, 182b, and 182c) include a blue color filter layer, a green color filter layer, and a red color filter layer, and can selectively transmit light of different wavelengths. The color filter layers 182a, 182b and 182c that transmit light of different colors are respectively provided in different emission areas. The light-shielding layer 181 serves to absorb all light in the visible spectrum, and can prevent or reduce external light from being visible. The color filters 182 (182a, 182b, and 182c) absorb light of wavelengths other than a predetermined wavelength, and can serve to prevent or reduce external light from being visible together with the light-shielding layer 181. The color filters 182 (182a, 182b, and 182c) may overlap the edge of the light-shielding layer 181.

The light-shielding layer 181 does not overlap the emission areas E1 and E2 and the first transmissive area T1 in the active area AA, does not overlap the dummy patterns DE1 and DE2 and the second transmissive area T2 in the dummy pixel part DPB, and does not overlap the openings ADE1 and ADE2 and the third transmissive area T3 in the capacitance compensation part AP.

The color filter array 180 may further include the upper protective layer 183 to protect the light-shielding layer 181 and the color filters 182 (182a, 182b, and 182c).

The light-shielding layer 181 may include a black material or a light-absorbing material. The light-shielding layer 181 may include a material that absorbs at least one wavelength of visible light.

The color filters 182 (182a, 182b, and 182c) may include a color pigment. The color filters 182 (182a, 182b, and 182c) may include a material that selectively transmits light of a certain wavelength range and absorbs light of the remaining wavelength ranges.

The light-shielding layer 181 and the color filters 182 (182a, 182b, and 182c) included in the color filter array 180 may serve to absorb external light coming from above toward the display device 1000, thereby preventing or reducing reflection of the external light by the metals of the touch sensor 170 and the light-emitting element 150. In this case, the color filter array 180 disposed on the touch sensor 170 can replace a polarizing plate, and thus the polarizing plate positioned above the light-emitting element in the display device 1000 can be omitted, thereby achieving a slim and simplified structure of the display device.

The light-shielding layer 181 may be disposed to cover at least the area occupied by the first wiring layer 172 and the second wiring layer 174 of the touch sensor 170, thereby preventing or reducing external light from being transmitted to the first wiring layer 172 and the second wiring layer 174 and preventing or reducing glinting due to the wiring layers of the touch sensor 170. The first wiring layer 172 and the second wiring layer 174 are disposed in the area between emission areas, between transmissive areas, and between the emission area and a transmissive area, and are covered by the light-shielding layer 181.

The light-shielding layer 181 having the same shape may be provided on the encapsulation layer 160 in the active area AA, the plurality of dummy pixel parts DPB, and the capacitance compensation part AP. The light-shielding layer 181 may overlap an area between the emission areas E1 and E2, areas between the emission areas E1 and E2 and the first transmissive area TA1, and an area between the first transmissive areas TA1 in the active area AA.

The emission area E1 or E2 may include, for example, a blue emission area, a green emission area, and a red emission area emitting different colors. The color filter 182 may include the first color filter 182a disposed in the first emission area E1, the second color filter 182b disposed in the second emission area E2, and the third color filter 182c disposed in the third emission area E3 different from the first and second emission areas E1 and E2. The first to third emission areas E1, E2, and E3 may include emission layers emitting different colors in the intermediate layer 152 and thus emit different colors. In this case, the color filter 182 may transmit the color emitted from the corresponding emission area more clearly. Alternatively, the light-emitting element 150 included in each of the first to third emission areas E1, E2, and E3 may emit white light, and transmit light of a color corresponding to each emission area through the color filter 182 in the color filter array 180 above the touch sensor 170. When the light-emitting element emits white light, the intermediate layer 152 may be formed in a form in which a plurality of stacks including emission layers emitting a plurality of different colors is laminated.

The blue color filter 182a may overlap the blue emission area, the green color filter 182b may overlap the green emission area, and the red color filter 182c may overlap the red emission area. The color filters 182a, 182b, and 182c overlap the entire emission area E1 or E2 and have edges farther outside than the edge of the emission area E1 or E2 to overlap a part of the light-shielding layer 181 located outside the emission area E1 or E2.

The color filters 182a, 182b, and 182c may partially overlap the bank 155 between the emission areas E1 and E2, as shown in FIG. 9 to FIG. 11. Therefore, the color filters 182a, 182b, and 182c between the emission areas E1 and E2 overlap the light-shielding layer 181, thereby preventing or reducing light leakage and blocking light coming from the upper side to the side and light emitted from each of the emission areas E1 and E1 and traveling in the oblique direction to adjacent subpixels, thereby enabling viewing angle light shielding.

The upper protective layer 183 covering the light-shielding layer 181 and the color filter array 180 is a transparent insulating layer and may be an inorganic layer or an organic layer. In some cases, the upper protective layer 183 may be a multilayer layer. The upper insulating layer 183 may serve as a cover layer that protects the lower components at the outermost side of the display device 1000.

Referring to FIG. 5, in the display device 1000 according to an embodiment of the present disclosure, the emission areas E1 and E2 and the first transmissive area TA1 are spaced apart from each other in the active area AA on the plane, the dummy patterns DE1 and DE2 and the second transmissive area TA2 are spaced apart from each other in the dummy pixel part DPB, and the third transmissive area TA3 and the openings ADE1 and ADE2 are spaced apart from each other in the capacitance compensation part AP.

The first to third transmissive areas TA1, TA2, and TA3 have the same shape or similar shape and the same or similar width as openings in the light-shielding layer 181, and the emission areas E1 and E2, the dummy patterns DE1 and DE2, and the openings ADE1 and ADE2 have the same shape or similar shape and the same or similar width. Even if the viewer observes an image behind the substrate 100 through the second and third transmissive areas TA2 and TA3 in the non-active area NA as well as the active area AA, the viewer can have a similar visual sensation in the active area AA, the dummy pixel part DPB, and the capacitance compensation part AP according to the similar pattern shape of the light shielding layer 181.

The bank 155 may have openings corresponding to the first transmissive area TA1 and the emission areas E1 and E2. The edge of the first electrode 151 of the light-emitting element 150 overlaps with the bank 155, and the area of the first electrode 151 exposed from the bank 155 may become the emission areas E1 and E2.

The first electrode 151 of the active area AA includes a reflective electrode and may prevent or reduce the transistor TFT and the storage capacitor Cs from being visible. First electrode dummy patterns 151a and 154 are further provided in the dummy pixel part DPB and the capacitance compensation part AP on the same layer as the first electrode 151 of the active area AA to prevent or reduce the transistors, the capacitors, the lines DL and RL, and the first and second connection patterns 138 and 136 from being visible.

The first electrode 151 and the first electrode dummy patterns 151a and 154 include reflective electrodes and may overlap with the color filters 182a, 182b, and 182c. Accordingly, similar visibility and external light recognition for each area can be prevented or reduced.

In FIG. 2 and FIG. 5, the first emission area E1 is illustrated as an octagon, and the second emission area E2 is illustrated as a square, but the embodiment of the present disclosure is not limited thereto. In addition to an octagon or a square, the emission areas E1 and E2 may be a polygon including a hexagon, a decagon, a dodecagon, etc., or may be an area having a round portion. The emission areas may have different shapes, different sizes, and different arrangement densities.

The display device 1000 of the embodiments of the present disclosure includes the touch sensor 170 and the color filter array 180 provided on the encapsulation layer 160 that protects the light-emitting element 150. Since the transmissive area TA is provided under the touch sensor 170, the first and second wiring layers 172 and 174 of the touch sensor 170 and the color filter array 180 are disposed to maximize or improve the transmittance of the transmissive area TA.

The first and second wiring layers 172 and 174 of the touch sensor 170 include a metal component, have little resistance in transmitting a touch detection signal and a touch sensing signal, and may have a narrow line width. In the display device 1000 of the embodiments of the present disclosure, the first and second wiring layers 172 and 174 of the touch sensor 170 include a metal component, and thus the first and second wiring layers 172 and 174 are disposed such that they do not overlap with the emission areas EA1, EA2, and EA3 and the transmissive area TA.

The second wiring layer 174 may be a plurality of spaced sensor layer electrodes that detect electrostatic capacitance that changes according to touch, and the first wiring layer 172 may serve to electrically connect the spaced sensor layer electrodes of the second wiring layer 174 in a different layer from the second wiring layer 174.

The configuration of the touch sensor 170 and the color filter array 180 may be further provided in the dummy pixel part DPB and the capacitance compensation part AP for similar visual sensation in the active area AA and outside the active area AA.

The display device 1000 of the embodiments of the present disclosure has transmissive areas TA1, TA2, and TA3 in the active area AA and the non-active area NA, and thus an image on the back surface of the substrate is also visible through the non-active area NA, and the transmissive area and the transmission efficiency can be improved.

In the display device 1000 of the embodiments of the present disclosure, the openings of the light-shielding layers surrounding the transmissive areas in the non-active area and the active area have the same size, and thus visibility can be improved by preventing or reducing uneven display occurring when the transmissive area is provided in the non-active area around the active area.

The display device 1000 of the embodiments of the present disclosure further includes a data capacitance compensation part around the active area having a non-rectangular shape, and thus data line capacitance deviation between areas caused by a wiring line length difference between the areas can be alleviated, thereby enabling uniform data signal supply in a non-rectangular display device.

Since the display device 1000 of the embodiments of the present disclosure includes the data capacitance compensation part, it is possible to prevent or reduce luminance unevenness that occurs in the active area by causing data lines having differences in wiring line lengths to have similar capacitances.

The display device 1000 of the embodiments of the present disclosure includes the data capacitance compensation part provided in the non-active area around data lines having a short length instead of an additional area, and thus image quality can be improved without loss of a transmissive area or an emission area.

The display device 1000 of the embodiments of the present disclosure includes the data capacitance compensation part having the first connection pattern connected to data lines and the second connection pattern overlapping the reference line (first voltage line) without adding a separate process. Therefore, it is not necessary to increase or decrease the layer structure of the display device. It is advantageous for recycling and more advantageous for achieving an eco-friendly display device since production energy for producing the display device can be decreased and the use of hazardous production materials or regulated substances can be reduced.

The display device 1000 according to the embodiments of the present disclosure can reduce a defect rate by uniformizing the capacitances of data lines in respective areas and can achieve ESG (Environmental/Social/Governance) through the effect of reducing production energy according to process optimization.

A display device according to one embodiment of the present disclosure may comprise a substrate having a non-rectangular active area and a non-active area surrounding the active area, a plurality of emission areas and a plurality of first transmissive areas in the active area, a plurality of data lines and a plurality of first voltage lines disposed in a first direction and overlapping at least one of the plurality of emission areas, a capacitance compensation part disposed in the non-active area and connected to at least one data line extended to the non-active area among the plurality of data lines and an encapsulation layer over the plurality of emission areas and the plurality of first transmissive areas in the active area, and the capacitance compensation part in the non-active area.

In a display device according to one embodiment of the present disclosure, the capacitance compensation part may comprise a first connection pattern connected to the at least one data line in the non-active area, a second connection pattern connected to a first voltage line extended to the non-active area among the plurality of first voltage lines and at least one insulating layer between the first connection pattern and the second connection pattern.

In a display device according to one embodiment of the present disclosure, the capacitance compensation part may be provided for a data line having a shorter length in the first direction overlapping the active area than a data line having the longest length in the first direction overlapping the active area, among the plurality of data lines.

In a display device according to one embodiment of the present disclosure, the first voltage lines may comprise a reference line.

A display device according to one embodiment of the present disclosure may further comprise a dummy pixel part between the active area and the capacitance compensation part.

Each of the plurality of emission areas may comprise a light-emitting element including a first electrode, an intermediate layer, and a second electrode, and a transistor connected to the light-emitting element.

At least one dummy pixel of the dummy pixel part may include a first electrode dummy pattern and an electrode layer at a same layer as at least one electrode of the transistor.

In a display device according to one embodiment of the present disclosure, each of the first electrode and the first electrode dummy pattern may comprise a reflective electrode and overlaps a color filter.

A display device according to one embodiment of the present disclosure may further comprise a light-shielding layer over the encapsulation layer.

The light-shielding layer may include openings having a same shape in the active area, and the dummy pixel part and the capacitance compensation part in the non-active area.

The light-shielding layer may overlap an area between the emission areas, areas between the emission areas and the first transmissive areas, and an area between the first transmissive areas in the active area.

In a display device according to one embodiment of the present disclosure, the active area may include a plurality of scan lines in a second direction intersecting the first direction.

The scan lines may sequentially pass through the dummy pixel part and the capacitance compensation part and be connected to a gate-in-panel (GIP) located outside the capacitance compensation part in the non-active area.

In a display device according to one embodiment of the present disclosure, the dummy pixel part may further comprise a second transmissive area that does not overlap the first electrode dummy pattern.

A display device according to one embodiment of the present disclosure may further comprise a first light-shielding layer non-overlapping the plurality of emission areas and the plurality of first transmissive areas, and a first color filter layer overlapping the plurality of emission areas over the encapsulation layer.

A display device according to one embodiment of the present disclosure may further comprise at least one of a second light-shielding layer and a second color filter layer overlapping the capacitance compensation part.

A display device according to one embodiment of the present disclosure may further comprise a first light-shielding layer over the encapsulation layer, the first light-shielding layer overlapping an area between the on the plurality of emission areas, an area between the plurality of emission areas and the plurality of first transmissive areas, and an area between the plurality of first transmissive areas.

In a display device according to one embodiment of the present disclosure, the second light-shielding layer of the capacitance compensation part may have an opening having a same shape as an opening of the first light-shielding layer.

A display device according to one embodiment of the present disclosure may further comprise a third transmissive area adjacent to the capacitance compensation part in the non-active area.

In a display device according to one embodiment of the present disclosure, the capacitance compensation part may be not disposed at a curved corner portion in the non-active area.

In a display device according to one embodiment of the present disclosure, the capacitance compensation part may be connected to a data line closest to the non-active area among the plurality of data lines.

A display device according to one embodiment of the present disclosure may further comprise a dummy pixel part between the active area and the capacitance compensation part; and a second transmissive area in the non-active area.

In a display device according to one embodiment of the present disclosure, the encapsulation layer may be disposed above the plurality of data lines, the plurality of first voltage lines, and the capacitance compensation part.

A light-shielding layer may be disposed over the encapsulation layer. The light-shielding layer may not be overlapped with the plurality of emission areas, the plurality of first transmissive areas and the second transmissive area.

In a display device according to one embodiment of the present disclosure, the light-shielding layer may comprise openings having a same width in the plurality of first transmissive areas and the second transmissive area.

It will be apparent to those skilled in the art that various modifications and variations can be made in the present disclosure without departing from the spirit or scope of the present disclosure. Thus, it is intended that the present disclosure cover the modifications and variations of the present disclosure provided they come within the scope of the appended claims and their equivalents.

What is claimed is:

1. A display device comprising:
a substrate having a non-rectangular active area and a non-active area surrounding the active area;
a plurality of emission areas and a plurality of first transmissive areas in the active area;
a plurality of data lines and a plurality of first voltage lines disposed in a first direction and overlapping at least one of the plurality of emission areas;
a capacitance compensation part disposed in the non-active area and connected to at least one data line extended to the non-active area among the plurality of data lines; and
an encapsulation layer over the plurality of emission areas and the plurality of first transmissive areas in the active area, and the capacitance compensation part in the non-active area.

2. The display device of claim 1, wherein the capacitance compensation part comprises:
a first connection pattern connected to the at least one data line in the non-active area;
a second connection pattern connected to a first voltage line extended to the non-active area among the plurality of first voltage lines; and
at least one insulating layer between the first connection pattern and the second connection pattern.

3. The display device of claim 1, wherein the capacitance compensation part is provided for a data line having a shorter length in the first direction overlapping the active area than a data line having the longest length in the first direction overlapping the active area, among the plurality of data lines.

4. The display device of claim 1, wherein the first voltage lines comprise a reference line.

5. The display device of claim 1, further comprising a dummy pixel part between the active area and the capacitance compensation part,
wherein each of the plurality of emission areas comprises a light-emitting element including a first electrode, an intermediate layer, and a second electrode, and a transistor connected to the light-emitting element, and
wherein at least one dummy pixel of the dummy pixel part includes a first electrode dummy pattern and an electrode layer at a same layer as at least one electrode of the transistor.

6. The display device of claim 5, wherein each of the first electrode and the first electrode dummy pattern comprises a reflective electrode and overlaps a color filter.

7. The display device of claim 5, further comprising a light-shielding layer over the encapsulation layer,
wherein the light-shielding layer includes openings having a same shape in the active area, and in the dummy pixel part and the capacitance compensation part in the non-active area, and
wherein the light-shielding layer overlaps an area between the emission areas, areas between the emission areas and the first transmissive areas, and an area between the first transmissive areas in the active area.

8. The display device of claim 5, wherein the active area includes a plurality of scan lines in a second direction intersecting the first direction,
wherein the scan lines sequentially pass through the dummy pixel part and the capacitance compensation part and are connected to a gate-in-panel (GIP) located outside the capacitance compensation part in the non-active area.

9. The display device of claim 5, wherein the dummy pixel part further comprises a second transmissive area that does not overlap the first electrode dummy pattern.

10. The display device of claim 9, further comprising a first light-shielding layer non-overlapping the plurality of emission areas and the plurality of first transmissive areas, and a first color filter layer overlapping the plurality of emission areas over the encapsulation layer.

11. The display device of claim 10, further comprising at least one of a second light-shielding layer and a second color filter layer overlapping the capacitance compensation part.

12. The display device of claim 1, further comprising a first light-shielding layer over the encapsulation layer, the first light-shielding layer overlapping an area between the plurality of emission areas, an area between the plurality of emission areas and the plurality of first transmissive areas, and an area between the plurality of first transmissive areas.

13. The display device of claim 11, wherein the second light-shielding layer of the capacitance compensation part has an opening having a same shape as an opening of the first light-shielding layer.

14. The display device of claim 1, further comprising another transmissive area adjacent to the capacitance compensation part in the non-active area.

15. The display device of claim 1, wherein the capacitance compensation part is not disposed at a curved corner portion in the non-active area.

16. The display device of claim 1, wherein the capacitance compensation part is connected to a data line closest to the non-active area among the plurality of data lines.

17. The display device of claim 1, further comprising:
a dummy pixel part between the active area and the capacitance compensation part; and
a second transmissive area in the non-active area.

18. The display device of claim 17, wherein the encapsulation layer is disposed above the plurality of data lines, the plurality of first voltage lines, and the capacitance compensation part, and
a light-shielding layer is disposed over the encapsulation layer, and the light-shielding layer is not overlapped with the plurality of emission areas, the plurality of first transmissive areas and the second transmissive area.

19. The display device of claim 18, wherein the light-shielding layer comprises openings having a same width in the plurality of first transmissive areas and the second transmissive area.
